(19) United States
(12) Patent Application Publication
(10) Pub. No.: US 2022/0235234 A1
(43) Pub. Date: Jul. 28, 2022

(54) DIFFUSING AGENT COMPOSITION AND METHOD FOR PRODUCING SEMICONDUCTOR SUBSTRATE

(71) Applicant: TOKYO OHKA KOGYO CO., LTD., Kawasaki-shi (JP)

(72) Inventor: Shunichi MASHITA, Kawasaki-shi (JP)

(21) Appl. No.: 17/647,247

(22) Filed: Jan. 6, 2022

(30) Foreign Application Priority Data
Jan. 21, 2021 (JP) 2021-008238

(51) Int. Cl. C09D 7/63; C09D 5/24; C09D 7/20; H01L 21/225

(52) U.S. Cl. CPC C09D 7/63; H01L 21/2254; C09D 7/20; C09D 5/24

(57) ABSTRACT

A diffusing agent composition and a method for producing a semiconductor substrate using the diffusing agent composition. The diffusing agent composition includes an impurity diffusing component which is a phosphorus compound, and a solvent. The phosphorus compound has a stabilization energy of −3 kcal/mol or less, and is in an amount of 80% by mass or more relative to a total solid content in the diffusing agent composition.

### BACKGROUND OF THE INVENTION

### Field of the Invention

The present invention relates to a diffusing agent composition and a method for producing a semiconductor substrate.

### Related Art

A semiconductor substrate to be used in a semiconductor element for a transistor, a diode, a solar cell, etc. has been produced by diffusing an impurity diffusing component such as phosphorus and boron into a semiconductor substrate. Conventionally, a diffusing agent composition including phosphoric ester and a specific condensed product has been known as the diffusing agent composition including phosphorus as the impurity diffusing component (see Patent Document 1). However, the object of Patent Document 1 was to obtain a coating film having a film thickness required for sufficient diffusion into the element, and a thick coating film having a thickness of as thick as 700 nm was considered in Example.

For the above-mentioned semiconductor substrate, when a semiconductor substrate for a multi-gate element such as Fin-FET and Nano-Wire FET is produced, an impurity may be diffused into, for example, a semiconductor substrate which has a three-dimensional structure having nanometer-scale small voids on its surface. For example, an ion implantation method (see, e.g., Patent Document 2) and a chemical vapor deposition (CVD) method (see, e.g., Patent Document 3) have been known as methods for diffusing the impurity diffusing component into the semiconductor substrate. In the ion implantation method, the impurity diffusing component is ionized and implanted onto a surface of the semiconductor substrate. In the CVD method, an oxide film such as silicon oxide doped with the impurity diffusing component such as phosphorus and boron is formed on the semiconductor substrate by the CVD method, and then the semiconductor substrate on which the oxide film is formed is heated in, for example, an electric furnace to thereby diffuse the impurity diffusing component from the oxide film to the semiconductor substrate.

Patent Document 1: Japanese Unexamined Patent Application, Publication No. 2012-104721

Patent Document 2: Japanese Unexamined Patent Application, Publication No. H06-318559

Patent Document 3: PCT International Publication No. WO2014/064873

### SUMMARY OF THE INVENTION

However, in the ion implantation method as described in Patent Document 2, a point defect or a point defect cluster may be formed in a region near a surface of the semiconductor substrate depending on the type of ion when the ion is implanted in the semiconductor substrate. For example, when a CMOS element for a CMOS imaging sensor is formed by diffusing the impurity diffusing component in the semiconductor substrate using the ion implantation method, occurrence of such defect leads directly to performance deterioration of the element.

Furthermore, when the semiconductor substrate has, on its surface, a nano-scale three-dimensional structure such as a 3D structure for forming a multi-gate element called Fin-FET having a plurality of source fins, a plurality of drain fins, and a gate perpendicular to the fins, it is difficult in the ion implantation method for an ion to be uniformly implanted on a side surface and a top surface of the fins and the gate and on an entire inner surface of a concave portion surrounded by the fins and the gate.

When the impurity diffusing component is diffused into the semiconductor substrate having the nano-scale three-dimensional structure by the ion implantation method, the below-mentioned failure is caused even if the ion could be uniformly implanted. For example, when a logic LSI device is formed using a semiconductor substrate that has a 3D pattern including fine fins, a crystal in a material of the substrate such as silicon tends to be destroyed by the ion implantation. Such crystal damage is believed to cause a failure such as variation in device properties and occurrence of a standby leak current.

Furthermore, when the CVD method as described in Patent Document 3 is applied, there are problems in that it is difficult to cover an entire inner surface of a concave portion surrounded by fins and a gate with an oxide film including an impurity diffusing component and having a uniform film thickness due to the overhang phenomenon and in that depositing an oxide in an opening in the concave portion surrounded by the fins and the gate causes the opening to be obstructed with the oxide. Thus, in the ion implantation method and the CVD method, it is difficult to satisfactorily and uniformly diffuse the impurity diffusing component into the semiconductor substrate depending on surface profile of the semiconductor substrate.

In order to solve such problems, use of a coating-type diffusing agent composition has been considered. If an entire surface including an entire inner surface of nano-scale minute voids in a substrate that has, on its surface, a three-dimensional structure having the minute voids can be uniformly coated with the coating-type diffusing agent composition, the impurity can be uniformly diffused into the semiconductor substrate having such a 3D surface. However, when the nano-scale three-dimensional structure is coated with the diffusing agent composition, a coating film made of the diffusing agent composition is needed to be thinner. Nevertheless, when a very thin coating film is formed using the coating-type diffusing agent composition, a film formation ability or diffusivity of the impurity diffusing component may be poor.

The present invention has been made in view of the above-mentioned context and an object of the present invention is to provide a diffusing agent composition having excellent film formation ability and excellent diffusivity of an impurity diffusing component even when a thin coating film is formed; and a method for producing a semiconductor substrate using the diffusing agent composition.

The present inventors have found that the above-mentioned problems can be solved by using a diffusing agent composition including an impurity diffusing component (A) and a solvent (S), the impurity diffusing component (A) being a phosphorus compound (A1), the phosphorus compound (A1) having a stabilization energy of −3 kcal/mol or less, and the phosphorus compound (A1) being comprised in an amount of 80% by mass or more relative to a total solid content in the diffusing agent composition. Thus, the present invention has been completed.

A first aspect of the present invention relates to a diffusing agent composition to be used for diffusing an impurity into a semiconductor substrate to be subjected to diffusion,

the diffusing agent composition including an impurity diffusing component (A) and a solvent (S),

the impurity diffusing component (A) being a phosphorus compound (A1),

the phosphorus compound (A1) having a stabilization energy of −3 kcal/mol or less,

the stabilization energy being a value determined as a difference in Gibbs free energy before and after hydrogen bond formation by a monomolecular reaction with (CH₃)₃SiOH using a density functional theory as a calculation method, B3LYP as a density functional, and 6-31 g(d,p) as a basis function by a quantum-chemistry calculation program Gaussian 16 from Gaussian, Inc., and

the phosphorus compound (A1) being comprised in an amount of 80% by mass or more relative to a total solid content in the diffusing agent composition.

A second aspect of the present invention relates to a method for producing a semiconductor substrate, the method including:

coating a semiconductor substrate to be subjected to diffusion with the diffusing agent composition according to the first aspect to thereby form a coating film; and

diffusing an impurity diffusing component (A) in the diffusing agent composition into the semiconductor substrate to be subjected to diffusion.

According to the present invention, there can be provided a diffusing agent composition having excellent film formation ability and excellent diffusivity of an impurity diffusing component even when a thin coating film is formed; and a method for producing a semiconductor substrate using the diffusing agent composition.

### DETAILED DESCRIPTION OF THE INVENTION

### <Diffusing Agent Composition>

A diffusing agent composition is used for diffusing an impurity into a semiconductor substrate to be subjected to diffusion.

The diffusing agent composition includes an impurity diffusing component (A) and a solvent (S). The impurity diffusing component (A) is a phosphorus compound (A1). The phosphorus compound (A1) is included in an amount of 80% by mass or more relative to a total solid content in the diffusing agent composition.

The phosphorus compound (A1) in the diffusing agent composition has a stabilization energy of −3 kcal/mol or less. The stabilization energy is a value determined as a difference in Gibbs free energy before and after hydrogen bond formation by a monomolecular reaction with (CH₃)₃SiOH using a density functional theory as a calculation method, B3LYP as a density functional, and 6-31g(d,p) as a basis function by a quantum-chemistry calculation program Gaussian 16 from Gaussian, Inc.

Using such a diffusing agent composition, a coating film having excellent film formation ability and excellent diffusivity of the impurity diffusing component can be formed.

### (Semiconductor Substrate to be Subjected to Diffusion)

A semiconductor substrate to be subjected to diffusion is a semiconductor substrate to be used as a target into which the impurity diffusing component is diffused. Various semiconductor substrates which have been conventionally used as described above may be used without particular limitation as the semiconductor substrate to be subjected to diffusion. The semiconductor substrate to be subjected to diffusion is typically a silicon substrate. In the present invention, a p-type silicon substrate is suitably used as the silicon substrate because the impurity diffusing component contains phosphorus.

The semiconductor substrate such as the silicon substrate often includes a natural oxide film formed through natural oxidization of a surface of the semiconductor substrate. For example, the silicon substrate often includes a natural oxide film mainly made of SiO₂.

When the impurity diffusing component is diffused into the semiconductor substrate to be subjected to diffusion, the natural oxide film on the surface of the semiconductor substrate to be subjected to diffusion is typically removed using an aqueous hydrofluoric acid solution.

### (Impurity Diffusing Component (A))

The impurity diffusing component (A) is a phosphorus compound (A1). The phosphorus compound (A1) is not particularly limited as long as it meets the above-mentioned predetermined condition regarding the stabilization energy.

The phosphorus compound (A1) is preferably one or more selected from the group consisting of phosphoric ester represented by Formula (a1) below, phosphonic acid represented by Formula (a2) below, and phosphoric triamide represented by Formula (a3) below.

(HO)ₘ—P(═O)(OR¹)₃₋ₘ (a1)

In Formula (a1), R¹ is an aliphatic hydrocarbon group or an aromatic hydrocarbon group and m is 1 or 2.

In the phosphoric ester represented by Formula (a1), the aliphatic hydrocarbon group represented by R¹ has preferably 1 or more and 12 or less carbon atoms, more preferably 2 or more and 8 or less carbon atoms, and further preferably 2 or more and 5 or less carbon atoms. The aliphatic hydrocarbon group may be linear or branched. In the phosphoric ester represented by Formula (a1), the aromatic hydrocarbon group represented by R¹ is preferably an aromatic hydrocarbon group having 6 or more and 12 or less carbon atoms.

Suitable examples of the aromatic hydrocarbon group having 1 or more and 12 or less carbon atoms represented by R¹ include a methyl group, an ethyl group, an n-propyl group, an isopropyl group, an n-butyl group, a sec-butyl group, an isobutyl group, a tert-butyl group, an n-pentyl group, an isopentyl group, a neopentyl group, a cyclopentyl group, an n-hexyl group, a 2-ethylhexyl group, a cyclohexyl group, an n-heptyl group, a cycloheptyl group, an n-octyl group, a cyclooctyl group, an n-nonyl group, an n-decyl group, an n-undecyl group, and an n-dodecyl group.

Suitable examples of the aromatic hydrocarbon group having 6 or more and 12 or less carbon atoms represented by R¹ include a phenyl group, a 2-methyl phenyl group, a 3-methyl phenyl group, a 4-methyl phenyl group, a 2-ethyl phenyl group, a 3-ethyl phenyl group, a 4-ethyl phenyl group, an α-naphthyl group, a β-naphthyl group, and a biphenylyl group.

Among the above-mentioned aliphatic hydrocarbon groups and aromatic hydrocarbon groups, the ethyl group, the isopropyl group, the n-butyl group, the 2-ethylhexyl group, and the phenyl group are preferred.

In Formula (a1), m is more preferably 2 than 1.

Examples of the phosphoric ester represented by Formula (a1) include phosphoric monoester and phosphoric diester. The phosphoric monoester is preferred from the viewpoint of excellent diffusion efficiency.

R²—P(═O)(OH)₂ (a2)

In Formula (a2), R² is an aliphatic hydrocarbon group or an aromatic hydrocarbon group.

In the phosphonic acid represented by Formula (a2), the aliphatic hydrocarbon group represented by R² is preferably an aliphatic hydrocarbon group having 1 or more and 12 or less carbon atoms. The aliphatic hydrocarbon group may be linear or branched. In the phosphonic acid represented by Formula (a2), the aromatic hydrocarbon group represented by R² is preferably an aromatic hydrocarbon group having 6 or more and 12 or less carbon atoms.

Suitable examples of the linear or branched aliphatic hydrocarbon group having 1 or more and 12 or less carbon atoms represented by R² include a methyl group, an ethyl group, an n-propyl group, an isopropyl group, an n-butyl group, a sec-butyl group, an isobutyl group, a tert-butyl group, an n-pentyl group, an isopentyl group, a neopentyl group, a cyclopentyl group, an n-hexyl group, a 2-ethylhexyl group, a cyclohexyl group, an n-heptyl group, a cycloheptyl group, an n-octyl group, a cyclooctyl group, an n-nonyl group, an n-decyl group, an n-undecyl group, and an n-dodecyl group.

Suitable examples of the aromatic hydrocarbon group having 6 or more and 12 or less carbon atoms represented by R² include a phenyl group, a 2-methyl phenyl group, a 3-methyl phenyl group, a 4-methyl phenyl group, a 2-ethyl phenyl group, a 3-ethyl phenyl group, a 4-ethyl phenyl group, an α-naphthyl group, a β-naphthyl group, and a biphenylyl group.

Among the above-mentioned aliphatic hydrocarbon group and aromatic hydrocarbon group, the phenyl group is preferred.

Specific examples of the phosphonic acid represented by Formula (a2) include phenyl phosphonic acid.

P(═O)(NR³₂)(NR⁴₂)(NR⁵₂) (a3)

In Formula (a3), R³, R⁴, and R⁵ are each independently a hydrogen atom, an aliphatic hydrocarbon group, or an aromatic hydrocarbon group.

In the phosphoric triamide represented by Formula (a3), the aliphatic hydrocarbon group represented by R³, R⁴, and R⁵ is preferably an aliphatic hydrocarbon group having 1 or more and 12 or less carbon atoms. The aliphatic hydrocarbon group may have a linear structure or a branched structure. In the phosphoric triamide represented by Formula (a3), the aromatic hydrocarbon group represented by R³, R⁴, and R⁵ is preferably an aromatic hydrocarbon group having 6 or more and 12 or less carbon atoms.

Suitable examples of the aliphatic hydrocarbon group having 1 or more and 12 or less carbon atoms represented by R³, R⁴, and R⁵ include a methyl group, an ethyl group, an n-propyl group, an isopropyl group, an n-butyl group, a sec-butyl group, an isobutyl group, a tert-butyl group, an n-pentyl group, an isopentyl group, a neopentyl group, a cyclopentyl group, an n-hexyl group, a 2-ethylhexyl group, a cyclohexyl group, an n-heptyl group, a cycloheptyl group, an n-octyl group, a cyclooctyl group, an n-nonyl group, an n-decyl group, an n-undecyl group, and an n-dodecyl group.

Suitable examples of the aromatic hydrocarbon group having 1 or more and 12 or less carbon atoms represented by R³, R⁴, and R⁵ include a phenyl group, a 2-methyl phenyl group, a 3-methyl phenyl group, a 4-methyl phenyl group, a 2-ethyl phenyl group, a 3-ethyl phenyl group, a 4-ethyl phenyl group, an α-naphthyl group, a β-naphthyl group, and a biphenylyl group.

Among the above-mentioned hydrogen atom, aliphatic hydrocarbon group, and aromatic hydrocarbon group, the hydrogen atom and the methyl group are preferred.

Specific examples of the phosphoric triamide represented by Formula (a3) include N,N-dimethyltriamidophosphoric acid and N,N,N′,N′,N″,N″-hexamethyltriamidophosphoric acid.

The phosphorus compound (A1) is, as mentioned above, contained in an amount of 80% by mass or more, preferably 90% by mass or more, more preferably 95% by mass or more relative to a total solid content in the diffusing agent composition. When the phosphorus compound (A1) is contained in an amount of less than 80% by mass relative to a total solid content in the diffusing agent composition, a less amount of the phosphorus compound (A1) diffuses even at the same film thickness due to the decreased amount of the phosphorus compound (A1), which makes it difficult to achieve a needed diffusion amount.

The stabilization energy of the phosphorus compound (A1) is −3 kcal/mol or less, as mentioned above. The stabilization energy is indicative of the film formation ability. From the comparison of the experimental results regarding the film formation ability, it is thought that stable film formation can be achieved when the stabilization energy is −3 kcal/mol or less.

The stabilization energy is a value determined as a difference in Gibbs free energy (AG) before and after hydrogen bond formation by a monomolecular reaction of the phosphorus compound (A1) with (CH₃)₃SiOH using a quantum-chemistry calculation program Gaussian 16 from Gaussian, Inc., as mentioned above. The (CH₃)₃SiOH is used herein as a model compound that assumes a surface of a silicon substrate. The AG may be calculated from the expression below.

ΔG=(Free energy of product)−(Sum of free energy of reactant)

### (Solvent (S))

Specific examples of the solvent (S) include monoethers of glycols such as ethylene glycol monomethyl ether, ethylene glycol monoethyl ether, ethylene glycol monopropyl ether, ethylene glycol monobutyl ether, propylene glycol monomethyl ether, propylene glycol monoethyl ether, propylene glycol monopropyl ether, propylene glycol monobutyl ether, diethylene glycol monomethyl ether, diethylene glycol monoethyl ether, diethylene glycol monopropyl ether, diethylene glycol monobutyl ether, diethylene glycol monophenyl ether, dipropylene glycol monomethyl ether, dipropylene glycol monoethyl ether, dipropylene glycol monopropyl ether, dipropylene glycol monobutyl ether, dipropylene glycol monophenyl ether, triethylene glycol monomethyl ether, triethylene glycol monoethyl ether, tripropylene glycol monomethyl ether, and tripropylene glycol monoethyl ether; monoethers such as diisopentyl ether, diisobutyl ether, benzyl methyl ether, benzyl ethyl ether, dioxane, tetrahydrofuran, anisole, perfluoro-2-butyltetrahydrofuran, and perfluorotetrahydrofuran; chain diethers of glycols such as ethylene glycol dimethyl ether, ethylene glycol diethyl ether, ethylene ethylene glycol dipropyl ether, ethylene glycol dibutyl ether, propylene glycol dimethyl ether, propylene glycol diethyl ether, propylene glycol dipropyl ether, propylene glycol dibutyl ether, diethylene glycol dimethyl ether, diethylene glycol diethyl ether, diethylene glycol dipropyl ether, diethylene glycol dibutyl ether, dipropylene glycol dimethyl ether, dipropylene glycol diethyl ether, dipropylene glycol dipropyl ether, and dipropylene glycol dibutyl ether; cyclic diethers such as 1,4-dioxane; ketones such as 1-octanone, 2-octanone, 1-nonanone, 2-nonanone, acetone, 2-heptanone, 4-heptanone, 1-hexanone, 2-hexanone, 3-pentanone, diisobutyl ketone, cyclohexanone, methyl cyclohexanone, phenylacetone, methyl ethyl ketone, methyl isobutyl ketone, ethyl isobutyl ketone, acetylacetone, acetonylacetone, ionone, diacetonyl alcohol, acetylcarbinol, acetophenone, methyl naphthyl ketone, and isophorone; esters such as methyl acetate, butyl acetate, ethyl acetate, isopropyl acetate, pentyl acetate, isopentyl acetate, methoxyethyl acetate, ethoxyethyl acetate, ethylene glycol monomethyl ether acetate, ethylene glycol monoethyl ether acetate, ethylene glycol monopropyl ether acetate, ethylene glycol monobutyl ether acetate, ethylene glycol monophenyl ether acetate, propylene glycol monomethyl ether acetate, propylene glycol monoethyl ether acetate, propylene glycol monopropyl ether acetate, propylene glycol monobutyl ether acetate, propylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl-3-methoxy propionate, ethyl-3-methoxy propionate, ethyl-3-ethoxy propionate, propyl-3-methoxy propionate, and isopropyl-3-methoxy propionate, propylene carbonate, and γ-butyrolactone; amido solvents containing no active hydrogen atom such as N-methyl-2-pyrrolidone, N,N-dimethylacetamide, N,N-dimethylformamide, hexamethyl phosphoric triamide, and 1,3-dimethyl-2-imidazolidinone; sulfoxides such as dimethyl sulfoxide; aliphatic hydrocarbon solvents optionally containing halogen such as pentane, hexane, octane, decane, 2,2,4-trimethylpentane, 2,2,3-trimethylhexane, perfluorohexane, perfluoroheptane, limonene, and pinene; aromatic hydrocarbon solvents such as benzene, toluene, xylene, ethylbenzene, propylbenzene, 1-methylpropylbenzene, 2-methylpropylbenzene, diethylbenzene, ethylmethylbenzene, trimethylbenzene, ethyl dimethylbenzene, and dipropylbenzene; monohydric alcohols such as methanol, ethanol, n-propanol, isopropanol, butanol, isobutanol, 2-methoxyethanol, 2-ethoxyethanol, 3-methyl-3-methoxybutanol, hexanol, cyclohexanol, benzyl alcohol, and 2-phenoxyethanol; glycols such as ethylene glycol, propylene glycol, diethylene glycol, and dipropylene glycol. Note that, an organic solvent containing an ether bond and an ester bond is classified under esters in the above-exemplified preferred organic solvent (S). These may be used alone or two or more thereof may be used in combination.

The diffusing agent composition may include various additives such as a surfactant, an antifoaming agent, a pH adjusting agent, and a viscosity adjusting agent unless it impairs the object of the present invention.

### <Method for Producing Semiconductor Substrate>

A method for producing a semiconductor substrate preferably includes coating a semiconductor substrate to be subjected to diffusion with the diffusing agent composition to thereby form a coating film; and diffusing an impurity diffusing component (A) in the diffusing agent composition into the semiconductor substrate to be subjected to diffusion.

Hereinafter, the formation of the coating film may be referred to as “coating step” and the diffusion of the impurity diffusing component (A) into the semiconductor substrate to be subjected to diffusion may be referred to as “diffusion step”.

Furthermore, a pre-diffusion heat treatment step in which the semiconductor substrate to be subjected to diffusion on which the coating film is formed is treated at a temperature lower than a diffusion temperature for a predetermined time may be performed between the coating step and the diffusion step.

### (Coating Step)

In the coating step, the coating film is formed by coating the semiconductor substrate to be subjected to diffusion with the diffusing agent composition. A method for coating the semiconductor substrate to be subjected to diffusion with the diffusing agent composition is not particularly limited as long as it can form a coating film having a predetermined film thickness. The method for the semiconductor substrate to be subjected to diffusion with the diffusing agent composition is preferably a spin coating method, an inkjet method, and a spraying method, and particularly preferably a spin coating method.

The film thickness of the coating film formed using the diffusing agent composition is not particularly limited. The film thickness of the coating film is preferably 30 nm or less, more preferably 0.2 nm or more and 30 nm or less, further preferably 0.2 nm or more and 10 nm or less, particularly preferably 0.5 nm or more and 10 nm or less, and most preferably 1 nm or more and 10 nm or less.

Note that, the film thickness of the coating film is an average value of film thicknesses at 5 or more positions as measured by an ellipsometer.

The semiconductor substrate to be subjected to diffusion may have a 3D structure having a convex portion and a concave portion on its surface to be coated with the diffusing agent composition. Use of the diffusing agent composition allows a thin coating film having, for example, a thickness of 30 nm or less to be easily and uniformly formed on the 3D structure of the semiconductor substrate to be subjected to diffusion even when the semiconductor substrate to be subjected to diffusion has such a 3D structure, in particular, a 3D structure having a nano-scale fine pattern on its surface.

A shape of the pattern is not particularly limited. Typical examples thereof include a straight or curved line or groove having a rectangle cross-section, and a hole-like shape.

It is also preferred that a surface of the semiconductor substrate to be subjected to diffusion is rinsed with an organic solvent after the semiconductor substrate to be subjected to diffusion is coated with the diffusing agent composition. The film thickness of the coating film may be more uniform by rinsing the surface of the semiconductor substrate to be subjected to diffusion. In particular, when the semiconductor substrate to be subjected to diffusion has a 3D structure on its surface, the coating film tends to be thicker at the bottom (concave portion) of the 3D structure. However, the film thickness of the coating film may be more uniform by rinsing the surface of the semiconductor substrate to be subjected to diffusion after the coating film is formed.

### (Pre-Diffusion Heat Treatment Step)

In the pre-diffusion heat treatment step, the semiconductor substrate to be subjected to diffusion is heat-treated at a temperature lower than a diffusion temperature between the formation of the coating film and the initiation of diffusion of the impurity diffusing component (A). A condition under which such heat treatment is performed is preferably 50° C. or more and 200° C. or less for 5 seconds or more and 5 minutes or less. The pre-diffusion heat treatment is preferably performed at a constant temperature.

When the semiconductor substrate to be subjected to diffusion on which the coating film is formed is heat-treated at a temperature lower than a diffusion temperature for a predetermined time, the impurity diffusing component (A) may be prevented from subliming and may be improved in diffusivity (in-plane uniformity and resistance) depending on a type of the impurity diffusing component (A).

A preferred temperature in the pre-diffusion heat treatment is, for example, in a range of 50° C. or more and 200° C. or less and more preferably in a range of 60° C. or more and 150° C. or less.

A heat treatment time in the pre-diffusion heat treatment step is preferably 5 seconds or more and 5 minutes or less and more preferably 10 seconds or more and 3 minutes or less from the viewpoint of a balance between the effect of improving impurity diffusivity of the pre-diffusion heat treatment step and production efficiency of the semiconductor substrate.

### (Diffusion Step)

In the diffusion step, the impurity diffusing component (A) in the thin coating film formed with the diffusing agent composition on the semiconductor substrate to be subjected to diffusion is diffused into the semiconductor substrate to be subjected to diffusion. A method for diffusing the impurity diffusing component (A) in the semiconductor substrate to be subjected to diffusion is not particularly limited as long as the impurity diffusing component (A) is diffused by heating from the coating film made of the diffusing agent composition. Note that, as used herein, the “diffusion step” shall be a step from a time point at which a temperature reaches a predetermined diffusion temperature to a time point by which a diffusion time (holding time at the diffusion temperature) has elapsed.

Typical examples thereof include a method in which the semiconductor substrate to be subjected to diffusion on which the coating film made of the diffusing agent composition is formed is heated in a heating furnace such as an electric furnace. In this case, a heating condition is not particularly limited as long as the impurity diffusing component (A) is diffused to the desired extent.

The impurity diffusing component (A) is preferably heated for diffusing at 700° C. or more and 1400° C. or less and more preferably 700° C. or more and less than 1200° C. for preferably 1 second or more and 20 minutes or less and more preferably 1 second or more and 1 minute or less.

Furthermore, when the semiconductor substrate can be rapidly heated to the predetermined diffusion temperature at a heating rate of 25° C./second or more, the diffusion time (holding time at the diffusion temperature) may be very short, for example, 30 seconds or less, 10 seconds or less, 5 seconds or less, 3 seconds or less, 2 seconds or less, or less than 1 second. A lower limit of the diffusion time is not particularly limited as long as the impurity diffusing component (A) can be diffused to the desired extent. The lower limit of the diffusion time may be, for example, 0.05 seconds or more, 0.1 seconds or more, 0.2 seconds or more, 0.3 seconds or more, or 0.5 seconds or more. In this case, the impurity diffusing component (A) easily diffuses at a high concentration in a shallow region on the surface of the semiconductor substrate to be subjected to diffusion.

In the diffusion step, an atmosphere around the semiconductor substrate to be subjected to diffusion while the semiconductor substrate to be subjected to diffusion is heated is preferably an atmosphere having an oxygen concentration of 1% by volume or less. The oxygen concentration in the atmosphere is more preferably 0.5% by volume or less, further preferably 0.3% by volume or less, particularly preferably 0.1% by volume or less, and most preferably 0% by mass.

The oxygen concentration in the atmosphere is adjusted to a desired concentration at any timing in a step previous to the diffusion step. A method for adjusting the oxygen concentration is not particularly limited. The method for adjusting the oxygen concentration may be a method in which an inert gas such as a nitrogen gas is circulated in a device for heating the semiconductor substrate to be subjected to diffusion to thereby discharge oxygen within the device along with the inert gas. In this method, the oxygen concentration in the device can be adjusted by adjusting the time during which the inert gas is circulated. The longer the time the inert gas is circulated, the lower the oxygen concentration in the device is.

When the diffusion is performed under a low-oxygen atmosphere, it is believed that silicon oxide is less likely to be formed from oxygen on the surface of the semiconductor substrate to be subjected to diffusion. As a result, the impurity diffusing component (A) more easily diffuses into a substrate mainly including silicone, and thus the impurity diffusing component (A) is improved in in-plane uniformity.

Depending on the above-mentioned conditions of the diffusion step, a residue from the impurity diffusing component (A) may adhere to a surface of the semiconductor substrate to be subjected to diffusion into which the impurity diffusing component (A) has been diffused after the diffusion step or near the surface, or a high-concentration layer which includes an excessively high concentration of the impurity diffusing component (A) may be formed.

When a semiconductor device is produced using the semiconductor substrate produced through the diffusion step, such adhesion of the residue or formation of the high-concentration layer may adversely affect performance of the semiconductor device.

In this case, the residue or the high-concentration layer is preferably removed after the diffusion step.

The residue and the high-concentration layer which are formed in the present invention can be removed by the below-mentioned method, as needed.

After the diffusion step, the surface of the semiconductor substrate is preferably treated by bringing into contact with an aqueous hydrofluoric acid (HF) solution. Such a treatment can remove the residue adhered to the surface of the semiconductor substrate.

A concentration of the aqueous hydrofluoric acid solution is not particularly limited as long as the residue can be removed. The concentration of the aqueous hydrofluoric acid solution is, for example, preferably 0.05% by mass or more and 5% by mass or less and more preferably 0.1% by mass or more and 1% by mass or less.

A temperature at which the surface of the semiconductor substrate is brought into contact with the aqueous hydrofluoric acid solution is not particularly limited as long as the residue can be removed.

The temperature at which the surface of the semiconductor substrate is brought into contact with the aqueous hydrofluoric acid solution is, for example, preferably 20° C. or more and 40° C. or less and more preferably 23° C. or more and 30° C. or less.

A time during which the surface of the semiconductor substrate is in contact with the aqueous hydrofluoric acid solution is not particularly limited as long as the residue can be removed and the semiconductor substrate is not unacceptably damaged. The time during which the surface of the semiconductor substrate is in contact with the aqueous hydrofluoric acid solution is, for example, preferably 15 seconds or more and 5 minutes or less and more preferably 30 seconds or more and 1 minute or less.

Furthermore, the surface of the semiconductor substrate is also preferably subjected to plasma ashing before the treatment with the aqueous hydrofluoric acid solution. Such a treatment can remove the high-concentration layer formed on or in the vicinity of the surface of the semiconductor substrate in addition to the residue.

The plasma ashing is preferably plasma ashing using an oxygen-containing gas and more preferably oxygen plasma ashing.

Various gases which have conventionally been used for plasma treatment together with oxygen can be mixed into a gas to be used for generating oxygen plasma within a range where the object of the present invention is not impaired. Examples of such a gas include a nitrogen gas, a hydrogen gas, etc.

Conditions for the plasma ashing are not particularly limited unless the object of the present invention is impaired.

According to the above-mentioned method, a coating film that is thin and has excellent post-formation stability is formed using the diffusing agent composition and, at the same time, the impurity diffusing component easily diffuses into the semiconductor substrate to be subjected to diffusion satisfactorily and uniformly. Therefore, the above-mentioned production method can be suitably applied to production of not only a semiconductor substrate having a flat surface but also a semiconductor substrate to be used for producing a multi-gate element having a fine 3D structure. The method according to the present invention can be suitably applied to, in particular, production of a CMOS element for a CMOS imaging sensor and a semiconductor element such as a logic LSI device.

### EXAMPLES

Hereinafter, the present invention will be more specifically described with reference to Examples and Comparative Examples, but the present invention is not limited to the following Examples.

### Examples 1 to 4

### (Preparation of Diffusing Agent Composition)

The below-mentioned phosphorus compound (A1) was dissolved into the below-mentioned solvent (S) to a concentration of 10 mmol/kg to thereby prepare each of the diffusing agent compositions of Examples 1 to 4 shown in Table 1.

The below-mentioned A1-1 to A1-4 were used as the phosphorus compound (A1).

Note that, a numerical value in parentheses just behind a compound name of each of the phosphorus compounds as A1-1 to A1-4 denotes stabilization energy of each of the phosphorus compounds (unit: kcal/mol). The stabilization energy is a value determined as a difference in Gibbs free energy before and after hydrogen bond formation by a monomolecular reaction with (CH₃)₃SiOH using a density functional theory as a calculation method, B3LYP as a density functional, and 6-31g(d,p) as a basis function by a quantum-chemistry calculation program Gaussian 16 from Gaussian, Inc.

For example, stabilization energy AG of monoisopropyl phosphate as A1-1 below is calculated as ΔG=ΔG_{C}−(ΔG_{A}+ΔG_{B})=−3.957 (kcal/mol) from free energy of monoisopropyl phosphate ΔG_{A}=−478162.950 (kcal/mol), free energy of (CH₃)₃SiOH ΔG_{B}=−304380.607 (kcal/mol), and free energy of product ΔG_{C}=−782547.514 (kcal/mol).

A1-1: isopropyl phosphate (mixture of monoisopropyl phosphate and diisopropyl phosphate) (monoisopropyl phosphate (−3.96), diisopropyl phosphate (−5.81))
A1-2: ethyl phosphate (mixture of monoethyl phosphate and diethyl phosphate) (monoethyl phosphate (−4.29), diethyl phosphate (−4.26))
A1-3: monophenyl phosphate (−4.31)
A1-4: diphenyl phosphate (−4.07)

The below-mentioned S1 was used as the solvent (S).

S1: mixed solvent of 70% by mass of propylene glycol monomethyl ether acetate (PGMEA) and 30% by mass of propylene glycol monomethyl ether (PGME)

### (Diffusion Treatment)

A surface of a p-type silicon substrate was coated with each of the diffusing agent compositions of Examples 1 to 4 using a spin coater at 1000 rpm and prebaked at 100° C. for 1 minute to thereby form the coating film having a film thickness shown in Table 1.

The silicon substrate with the coating film was subjected to a diffusion treatment under a nitrogen atmosphere at a diffusion temperature of 1000° C. for a diffusion time of 10 seconds using a rapid thermal annealing device (ramp annealing device). After the completion of diffusion, the silicon substrate was rapidly cooled to room temperature.

### (Evaluation)

It was verified whether the silicon substrate was inversed from p-type to n-type after the diffusion treatment. When the substrate was inversed, it was evaluated as good (indicated by circle symbol (o)) and when the substrate was not inversed, it was evaluated as poor (indicated by cross symbol (x)). Furthermore, the silicon substrate after diffusion treatment was measured for a sheet resistance value. The results are shown in Table 1.

Note that, in Examples 1 and 2 in Table 1, stabilization energy of the phosphoric monoester and the phosphoric diester were shown in the top and bottom parts, respectively, under the heading of “Stabilization energy”.

TABLE 1

| | Phosphorus | | | | Sheet | | |
|---|---|---|---|---|---|---|---|
| | compound (A1) | | Solvent | Film | resistance | | Stabilization |
| | | Content | (S) | thickness | value | | energy |
| | Type | (% by mass) | Type | (nm) | (Ω/cm²) | Diffusivity | (kcal/mol) |
| Example 1 | A1-1 | 100 | S1 | 4.1 | 379.3 | ∘ | (mono)−3.96 |
| | | | | | | | (di)−5.81 |
| Example 2 | A1-2 | 100 | S1 | 3.7 | 343.6 | ∘ | (mono)−4.29 |
| | | | | | | | (di)−4.26 |
| Example 3 | A1-3 | 100 | S1 | 5.6 | 380.7 | ∘ | −4.31 |
| Example 4 | A1-4 | 100 | S1 | 12.1 | 839.5 | ∘ | −4.07 |

Table 1 demonstrates that the diffusing agent compositions of Examples 1 to 4 all had excellent film formation ability and diffusivity of the impurity diffusing component when the phosphoric ester of which stabilization energy was calculated as −3 kcal/mol or less was used as the phosphorus compound (A1). Moreover, Example 3 using monophenyl phosphate as the phosphorus compound (A1) had a greatly decreased sheet resistance value compared to Example 4 using diphenyl phosphate, indicating that the phosphoric monoester more efficiently diffuses.

### Examples 5 to 9 and Comparative Examples 1 to 4

### (Preparation of Diffusing Agent Composition)

The below-mentioned phosphorus compound (A1) was dissolved into the below-mentioned solvent (S) to a concentration of 1.65 mmol/kg to thereby prepare each of the diffusing agent compositions of Examples 5 to 9 and Comparative Examples 1 to 4 shown in Table 2.

The above-mentioned A1-1 and the below-mentioned A1-5 to A1-12 were used as the phosphorus compound (A1). Note that, a numerical value in parentheses just behind a compound name of each of the phosphorus compounds as A1-5 to A1-12 denotes stabilization energy of each of the phosphorus compounds (unit: kcal/mol).

A1-5: dibutyl phosphate (−3.98)
A1-6: mono(2-ethylhexyl) phosphate (−3.80)
A1-7: di(2-ethylhexyl) phosphate (−4.01)
A1-8: phenyl phosphonic acid (−4.80)
A1-9: triphenylphosphine oxide (−1.05)
A1-10: diethyl phosphoramidate (−1.71)
A1-11: diisopropyl phosphite (1.45)
A1-12: trimethyl phosphate (0.86)

The below-mentioned S1 was used as the solvent (S).

S1: mixed solvent of 70% by mass of propylene glycol monomethyl ether acetate (PGMEA) and 30% by mass of propylene glycol monomethyl ether (PGME)

### (Diffusion Treatment)

A surface of a p-type silicon substrate was coated with each of the diffusing agent compositions of Examples 5 to 9 and Comparative Examples 1 to 4 using a spin coater at 500 rpm and prebaked at 100° C. for 1 minute to thereby form the coating film having a film thickness shown in Table 2.

The silicon substrate with the coating film was subjected to a diffusion treatment under a nitrogen atmosphere at a diffusion temperature of 1000° C. for a diffusion time of 10 seconds using a rapid thermal annealing device (ramp annealing device). After the completion of diffusion, the silicon substrate was rapidly cooled to room temperature.

### (Evaluation)

It was verified whether the silicon substrate was inversed from p-type to n-type after the diffusion treatment. When the substrate was inversed, it was evaluated as good (indicated by circle symbol (o)) and when the substrate was not inversed, it was evaluated as poor (indicated by cross symbol (x)). Furthermore, the silicon substrate after diffusion treatment was measured for a sheet resistance value. The results are shown in Table 2.

TABLE 2

| | Phosphorus | | | | Sheet | | |
|---|---|---|---|---|---|---|---|
| | compound (A1) | | Solvent | Film | resistance | | Stabilization |
| | | Content | (S) | thickness | value | | energy |
| | Type | (% by mass ) | Type | (nm) | (Ω/cm²) | Diffusivity | (kcal/mol) |
| Example 5 | A1-5 | 100 | S1 | 3.8 | 4646.8 | ∘ | −3.98 |
| Example 6 | A1-6 | 100 | S1 | 8.6 | 878.8 | ∘ | −3.80 |
| Example 7 | A1-7 | 100 | S1 | 14.2 | 2650.3 | ∘ | −4.01 |
| Example 8 | A1-1 | 100 | S1 | 7.5 | 311.52 | ∘ | (mono)−3.96 |
| | | | | | | | (di)−5.81 |
| Example 9 | A1-8 | 100 | S1 | 11.5 | 2107.7 | ∘ | −4.80 |
| Comparative | A1-9 | 100 | S1 | Unmeasurable | 213.5 | x | −1.05 |
| Example 1 | | | | | | | |
| Comparative | A1-10 | 100 | S1 | 0.4 | 7744 | x | −1.71 |
| Example 2 | | | | | | | |
| Comparative | A1-11 | 100 | S1 | 0.2 | 14791 | x | 1.45 |
| Example 3 | | | | | | | |
| Comparative | A1-12 | 100 | S1 | 0 | 211.1 | x | 0.86 |
| Example 4 | | | | | | | |

Table 2 demonstrates as in Table 1 that the diffusing agent compositions of Examples 5 to 8 all had excellent film formation ability and diffusivity of the impurity diffusing component when the phosphoric ester having a stabilization energy of −3 kcal/mol or less was used as the phosphorus compound (A1). Moreover, it was demonstrated that the diffusing agent composition of Example 9 which contained A1-8 corresponding to phosphonic acid also has excellent film formation ability and diffusivity, although some particles were formed. Meanwhile, when the phosphorus compounds (A1) had a stabilization energy of much higher than −3 kcal/mol, all had poor diffusivity as shown in Comparative Examples 1 to 4. Comparative Example 1 was unmeasurable for film formation ability due to severe particle formation, and a film itself was not formed in Comparative Example 4.

### (Stabilization Energy of Phosphoric Triamide)

Stabilization energy of N,N-dimethyltriamidophosphoric acid corresponding to phosphoric triamide was calculated in the same manner as in Examples 5 to 9 and Comparative Examples 1 to 4.

The stabilization energy was calculated as −3.46 kcal/mol. It was assumed from this result that, as in the case of the phosphoric ester or the phosphonic acid, the phosphoric triamide also had excellent film formation ability and was likely to be suitably used as the phosphorus compound (A1).

What is claimed is:

1. A diffusing agent composition for diffusing an impurity into a semiconductor substrate to be subjected to diffusion, the diffusing agent composition comprising:
an impurity diffusing component (A) and a solvent (S),
wherein the impurity diffusing component (A) is a phosphorus compound (A1) having a stabilization energy of −3 kcal/mol or less,
wherein the stabilization energy is a value determined as a difference in Gibbs free energy before and after hydrogen bond formation by a monomolecular reaction with (CH₃)₃SiOH using a density functional theory as a calculation method, B3LYP as a density functional, and 6-31g(d,p) as a basis function by a quantum-chemistry calculation program Gaussian 16 from Gaussian, Inc., and
the phosphorus compound (A1) is 80% by mass or more relative to a total solid content in the diffusing agent composition.

2. The diffusing agent composition according to claim 1, wherein the phosphorus compound (A1) is 90% by mass or more relative to a total solid content in the diffusing agent composition.

3. The diffusing agent composition according to claim 1, wherein the phosphorus compound (A1) is one or more selected from the group consisting of a phosphoric ester represented by formula (a1) below, a phosphonic acid represented by formula (a2) below, and a phosphoric triamide represented by aormula (a3) below:
(HO)ₘ—P(═O)(OR¹)₃₋ₘ (a1)
wherein R¹ is an aliphatic hydrocarbon group or an aromatic hydrocarbon group and m is 1 or 2,
R²—P(═O)(OH)₂ (a2)
wherein R² is an aliphatic hydrocarbon group or an aromatic hydrocarbon group, and
P(═O)(NR³₂)(NR⁴₂)(NR⁵₂) (a3)
wherein R³, R⁴, and R⁵ are each independently a hydrogen atom, an aliphatic hydrocarbon group, or an aromatic hydrocarbon group.

4. The diffusing agent composition according to claim 3, wherein the phosphoric ester comprises a phosphoric monoester.

5. A method for producing a semiconductor substrate, the method comprising:
coating a semiconductor substrate to be subjected to diffusion with the diffusing agent composition according to claim 1 to form a coating film; and
diffusing an impurity diffusing component (A) in the diffusing agent composition into the semiconductor substrate to be subjected to diffusion.

6. The method for producing a semiconductor substrate according to claim 5, wherein the impurity diffusing component (A) is diffused into the semiconductor substrate to be subjected to diffusion by heating the coating film at a temperature of 700° C. or more and less than 1200° C.

7. The method for producing a semiconductor substrate according to claim 5, wherein the coating film has a film thickness of 30 nm or less.

8. The method for producing a semiconductor substrate according to claim 7, wherein the coating film has a film thickness of 0.2 nm or more and 10 nm or less.
